(19) United States
(12) Patent Application Publication
(10) Pub. No.: US 2011/0267777 A1
(43) Pub. Date: Nov. 3, 2011

(54) Cooling unit, electronic device, and heat sink

(75) Inventors: Shin Oike, Nagano (JP); Tomoyuki Tsukamoto, Nagano (JP)

(73) Assignee: Sony Corporation, Tokyo (JP)

(21) Appl. No.: 13/066,572

(22) Filed: Apr. 18, 2011

(30) Foreign Application Priority Data
Apr. 30, 2010 (JP) P2010-105835

(51) Int. Cl. H05K 7/20; F28F 13/00

(52) U.S. Cl. 361/697; 165/121

(57) ABSTRACT

A cooling unit includes: a case having an air inlet that sucks an air, an air outlet that discharges the sucked air, and a side wall that forms a ventilation path leading the air from the air inlet to the air outlet; a fan housed in the case; and a heat sink arranged in the air outlet of the case, having a plurality of heat dissipating fins, and having a dust and dirt discharging port formed at a position corresponding to a flow rate of the air flowing in the case.

### CROSS-REFERENCE TO RELATED APPLICATION

The present application claims priority from Japanese Patent Application No. JP 2010-105835 filed in the Japanese Patent Office on Apr. 30, 2010, the entire content of which is incorporated herein by reference.

### BACKGROUND OF THE INVENTION

1. Field of the Invention

The present invention relates to a cooling unit that prevents heat dissipating fins from dust clogging by dust and dirt entered in the unit, an electronic device provided with the cooling unit, and a heat sink used for the cooling unit.

2. Description of the Related Art

In the past, in an electronic device such as a personal computer, a cooling unit configured with a heat sink and a fan is used for cooling components that produce heat (hereinafter, referred to as “heat producing components”), such as an IC (integrated circuit) and a CPU (central processing unit). A heat sink is configured with a plurality of heat dissipating fins that are stacked at predetermined intervals.

However, together with an air, dust and dirt used to be sucked in a case of a cooling unit. Then, the sucked dust and dirt are attached between the heat dissipating fins configuring a heat sink, and thus so-called dust clogging used to occur. In addition, there used to be a problem that, when dust clogging occurs in a heat sink, the cooling capacity of the entire unit drops down.

In order to suppress the dust clogging in a heat sink, an air inlet of a cooling unit, for example, used to be equipped with a dust entrance prevention material including a patching mesh that prevents dust and dirt from entering in the past. Japanese Unexamined Patent Application Publication No. 2005-321287 describes a technique to discharge dust and dirt, by ramping heat dissipating fins and also forming a dust and dirt outlet in a case for housing of a fan and a heat sink, from the dust and dirt outlet.

### SUMMARY OF THE INVENTION

However, in the technique of providing a dust entrance prevention material in the past, a step of providing a dust entrance prevention material in an air inlet was desired when the unit is assembled. Therefore, there used to be a problem of not only an increase of the number of component items but also an increase of the number of steps when the unit is assembled.

In addition, in the technique described in Japanese Unexamined Patent Application Publication No. 2005-321287, a case is equipped with the dust and dirt outlet to discharge dust and dirt. Therefore, when the unit is assembled, a step of not only ramping heat dissipating fins but also forming a dust and dirt outlet in a case is desired, which used to make assembly of the unit complicated.

Further, not only there used to be a possibility of attaching dust and dirt to heat dissipating fins when dust and dirt flow on ramps provided in the heat dissipating fins but also a place to provide a dust and dirt outlet used to be set without considering the flow rate and the pressure of the air flowing in the case. Therefore, there also used to be a problem that it was difficult to effectively discharge dust and dirt and the dust and dirt remained undischarged were attached to the heat dissipating fins and the cooling capacity of the unit dropped down.

It is desirable to provide a cooling unit, an electronic device, and a heat sink that can effectively discharge dust and dirt from inside a case with a simple configuration and can prevent dust clogging.

According to an embodiment of the present invention, a cooling unit includes: a case having an air inlet that sucks an air, an air outlet that discharges the sucked air, and a side wall that forms a ventilation path leading the air from the air inlet to the air outlet; and a fan housed in the case. Further, it includes a heat sink arranged in the air outlet of the case, having a plurality of heat dissipating fins, and having a dust and dirt discharging port formed at a position corresponding to a flow rate of the air flowing in the case.

An electronic device of an embodiment of the present invention includes a heat producing unit mounted on a substrate and a cooling unit cooling the heat producing unit. Then, the cooling unit has: a case having an air inlet that sucks an air, an air outlet that discharges the sucked air, and a side wall that forms a ventilation path leading the air from the air inlet to the air outlet; and a fan housed in the case. Further, the cooling unit has a heat sink arranged in the air outlet of the case, having a plurality of heat dissipating fins, and having a dust and dirt discharging port formed at a position corresponding to a flow rate of the air flowing in the case. Then, the cooling unit has a heat receiving unit absorbing heat from the heat producing unit, and a heat transfer unit transferring the heat absorbed by the heat receiving unit to the heat sink.

A heat sink of an embodiment of the present invention is a heat sink arranged in an air outlet of a cooling unit having an air inlet that has a fan built therein and sucks an air, the air outlet that discharges the sucked air, and a side wall that forms a ventilation path leading the air from the air inlet to the air outlet. Then, the heat sink includes: a plurality of heat dissipating fins; and a dust and dirt discharging port formed at a position corresponding to a flow rate of the air flowing in the case of the cooling unit.

According to a cooling unit, an electronic device, and a heat sink of an embodiment of the present invention, a heat sink to which an air led from a ventilation path is blown from an air outlet is equipped with a dust and dirt outlet. Further, since a position to provide the dust and dirt outlet is a position corresponding to the flow rate of the air flowing in the case, dust and dirt can be discharged effectively. This enables to prevent that dust and dirt are attached to the case or the heat dissipating fins and that the cooling capacity drops down, and to suppress a rise in temperature of heat producing members, such as a CPU and an IC.

In addition, a dust entrance prevention material does not have to be equipped and a hole does not have to be opened in a case, so that dust and dirt can be discharged with an extremely simple configuration. As a result, it is also possible to simplify the steps for assembling the unit.

### BRIEF DESCRIPTION OF THE DRAWINGS

FIG. 1 is a perspective view illustrating a laptop PC that is applied as an electronic device according to an embodiment of the present invention;

FIG. 2 is an exploded perspective view illustrating the laptop PC that is applied as the electronic device according to the embodiment of the present invention;

FIG. 3 is a top view illustrating a main body related to the laptop PC that is applied as the electronic device according to the embodiment of the present invention;

FIG. 4 is a side view illustrating the main body related to the laptop PC that is applied as the electronic device according to the embodiment of the present invention;

FIG. 5 is an exploded perspective view illustrating a main portion of the laptop PC that is applied as the electronic device according to the embodiment of the present invention;

FIG. 6 is an exploded perspective view illustrating a cooling unit according to an embodiment of the present invention;

FIG. 7 is a front view illustrating a condition of removing an upper case related to the cooling unit according to the embodiment of the present invention;

FIG. 8 is a perspective view illustrating a heat sink related to the cooling unit according to the embodiment of the present invention;

FIG. 9 is a front view illustrating heat dissipating fins related to the cooling unit according to the embodiment of the present invention;

FIG. 10 is a distribution chart illustrating a pressure distribution in a case in the cooling unit according to the embodiment of the present invention;

FIG. 11 is a flow rate distribution chart illustrating a speed of an air flowing in the case in the cooling unit according to the embodiment of the present invention; and

FIG. 12 is a perspective view illustrating a heat sink related to a cooling unit according to another embodiment of the present invention.

### DESCRIPTION OF THE PREFERRED EMBODIMENTS

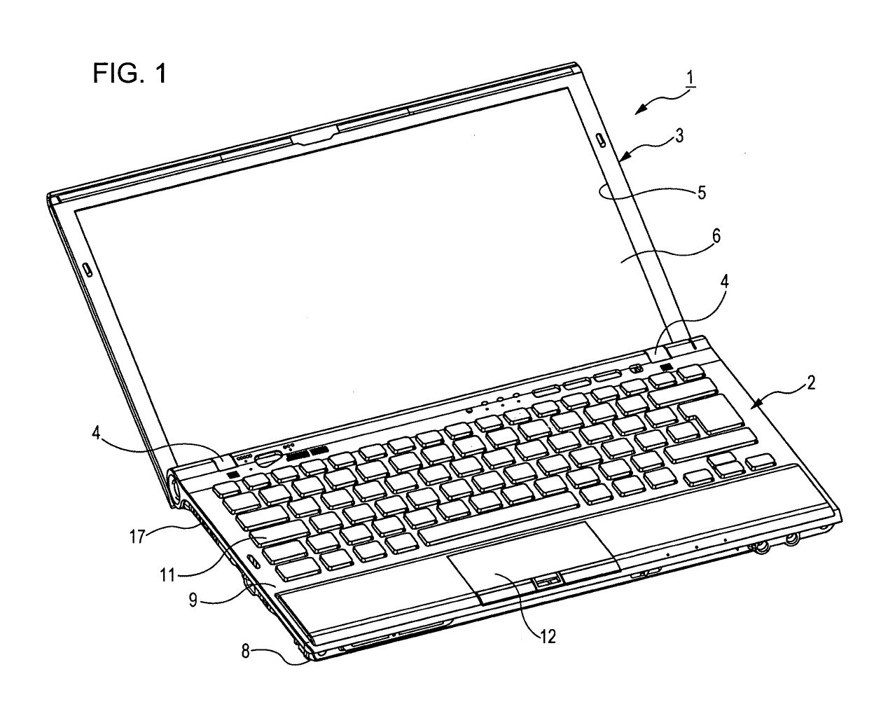

A description is given below to an electronic device and a cooling unit according to embodiments of the present invention with reference to FIGS. 1 through 12. In each diagram, identical reference characters are assigned to common members. Embodiments of the present invention are not limited to the embodiments below.

The description is given in the following order.

1. Embodiment
1-1. Configuration of Electronic Device
1-2. Behavior of Cooling Unit

2. Another Embodiment

### 1. Embodiment

### 1-1. Configuration of Electronic Device

Firstly, with reference to FIGS. 1 through 4, a description is given to an electronic device according to an embodiment of the present invention.

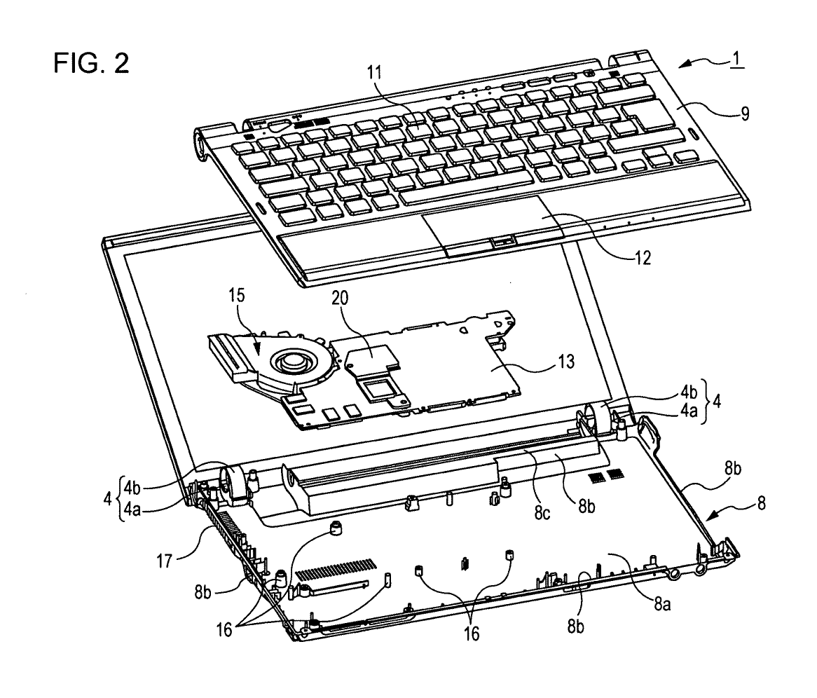

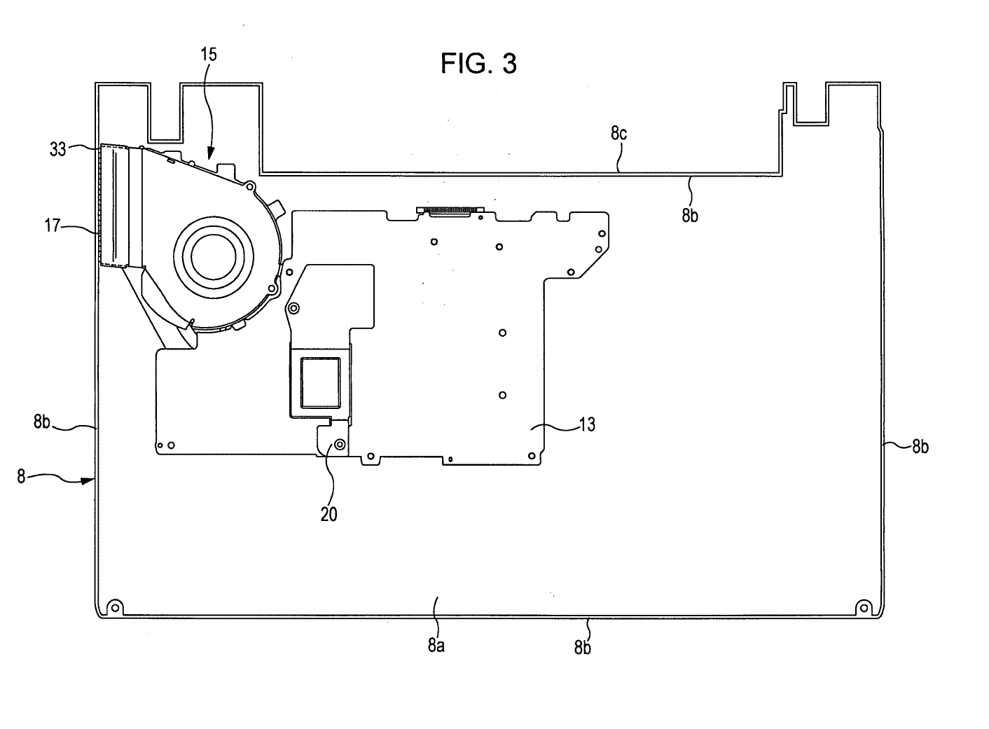

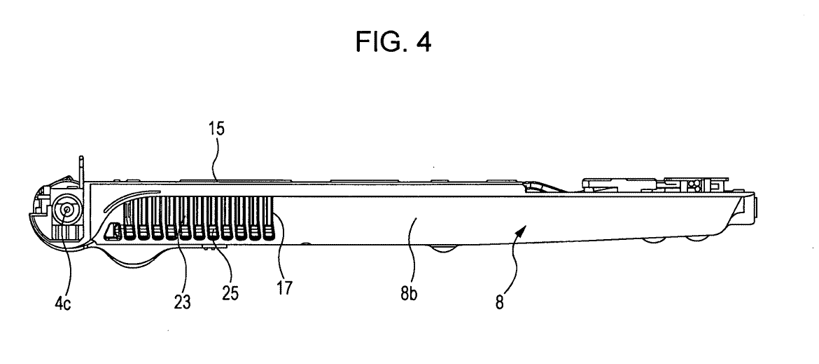

FIG. 1 is a perspective view illustrating an electronic device of the embodiment, and FIG. 2 is an exploded perspective view illustrating the electronic device of the embodiment. FIG. 3 is a top view illustrating a main body of the electronic device of the embodiment, and FIG. 4 is a side view illustrating the main body of the electronic device of the embodiment.

### [Electronic Device]

As shown in FIG. 1, an electronic device 1 of the embodiment is a laptop personal computer (hereinafter, referred to as “a laptop PC”). The laptop PC 1 is configured to be provided with a flat perpendicular parallelepiped main body 2, a similarly flat perpendicular parallelepiped display 3, and the like. The main body 2 and the display 3 are provided with a space in a predetermined size respectively and also are configured to be stackable by overlapping with each other. That is, the display 3 is stacked on the main body 2, and the main body 2 and the display 3 are turnably coupled by a hinge mechanism 4.

On a surface facing an upper surface of the main body 2, which is an inner surface of the display 3, an opening is equipped leaving a slight margin at the periphery. Towards the opening 5 of the display 3, there is a flat display panel 6, such as a liquid crystal display, an organic EL display, and a surface-conduction electron-emitter display, which is a display unit housed therein.

Inside the flat display panel 6, although not shown, a backlight applying light on a backside of the flat display panel 6, a wiring board having a control unit to control a screen of the flat display panel 6 mounted thereon, and the like are housed as desired. Then, it is configured to enable various types of information, images, and the like to be displayed on the flat display panel 6.

As shown in FIG. 2, the main body 2 is configured with a housing 8 formed in a container shape that is opened on one side and is flat and an input board 9 closing the opening of the housing 8. The input board 9 faces the opening 5 and the flat display panel 6 of the display 3 when overlapping the main body 2 with the display 3.

The input board 9 is equipped with a key input unit 11 including a large number of keys and a touch input unit 12. The touch input unit 12 carries out an input operation with a touchscreen input mechanism or the like. A control signal is inputted from the key input unit 11 and touch input unit 12 and predetermined information processing and the like are carried out.

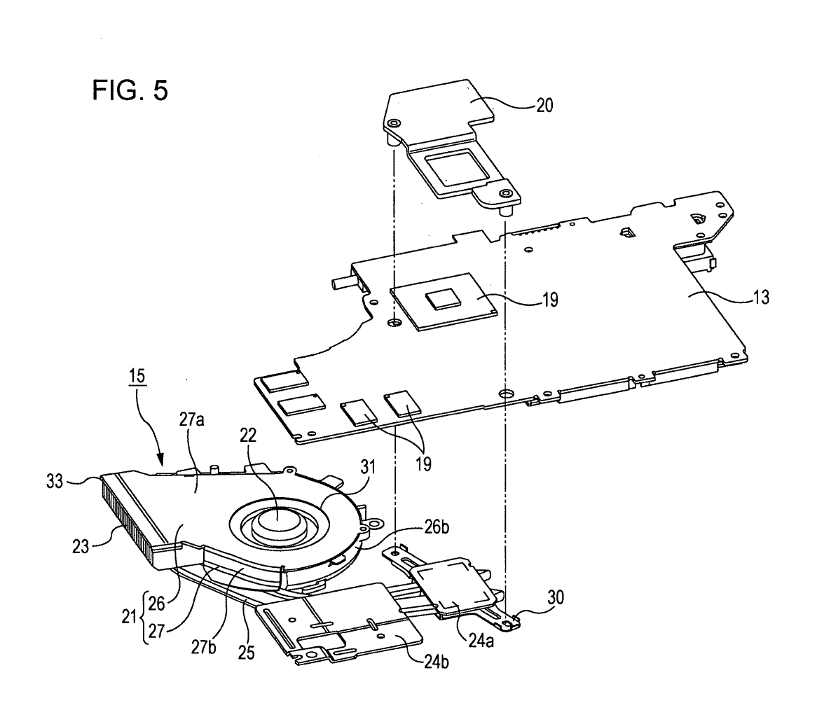

Inside the main body 2, housed are a disk drive not shown, a wiring board 13 having a control unit to control the disk drive unit and other units and devices mounted thereon, a cooling unit 15, and the like. On the wiring board 13, ICs and a CPU, which are heat producing components 19, are mounted (refer to FIG. 5).

The housing 8 has a principal surface 8a formed in an approximately quadrangular shape and four side faces 8b, 8b, 8b, and 8b surrounding the principal surface 8a. As shown in FIG. 3, on one side in width of the principal surface 8a, a recess 8c is provided. In the recess 8c, a battery power supply is arranged that is not shown and supplies power to the disk drive unit, the control unit, and the like. On both left and right sides of the recess 8c, main body side hinge portions 4a and 4a configuring the hinge mechanism 4 are arranged.

The hinge mechanism 4 is configured with a combination of one pair of main body side hinge portions 4a and 4a, one pair of display side hinge portions 4b and 4b, and a hinge axis 4c. The pair of display side hinge portions 4b and 4b is arranged at a position, corresponding to the pair of main body side hinge portions 4a and 4a arranged in the housing 8, on both backward sides of the display 3. As shown in FIG. 4, the hinge axis 4c penetrates the main body side hinge portion 4a and the display side hinge portion 4b.

The main body 2 and the display 3 are turnably coupled by the hinge mechanism 4, and thus the laptop PC 1 is configured in which the display 3 is vertically turnable relative to the main body 2. The display 3 is configured to be capable of keeping the ramped orientation at any angular position relative to the main body 2.

As shown back in FIG. 2, on the principal surface 8a of the housing 8, fixation units 16 are formed to fix the wiring board 13 and the cooling unit 15. The wiring board 13 and the cooling unit 15 are fixed to the principal surface 8a of the housing 8 by a fixation method, such as a fixation screw. As shown in FIG. 4, in the side face 8b located on one longitudinal end side of the principal surface 8a, a housing side air outlet 17 is formed.

### [Cooling Unit]

Next, a description is given to a configuration of the cooling unit of the embodiment with reference to FIGS. 5 through 7.

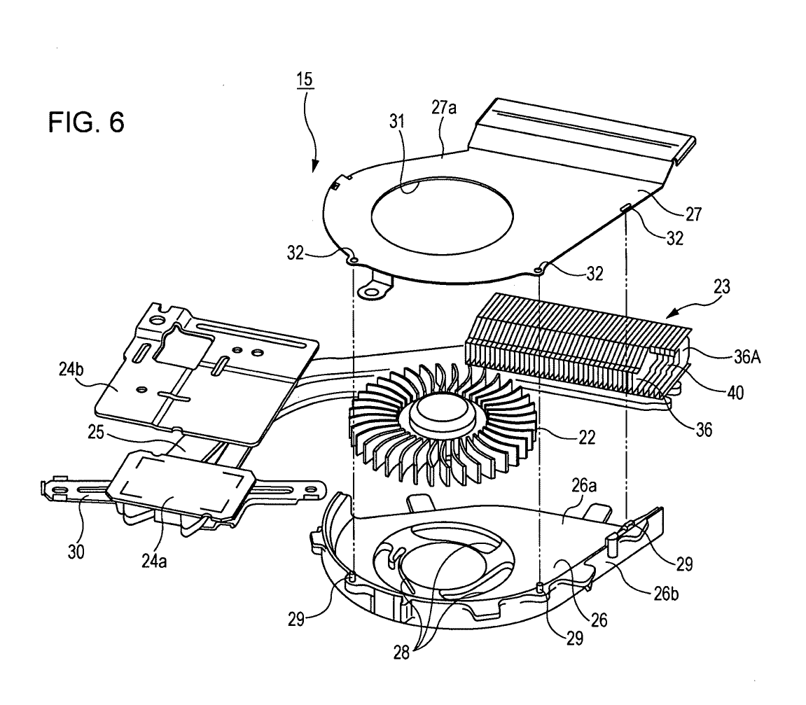

FIG. 5 is a perspective view illustrating a main portion of the laptop PC 1 of the embodiment, and FIG. 6 is an exploded perspective view illustrating the cooling unit 15 of the embodiment.

As shown in FIGS. 5 and 6, the cooling unit 15 is configured with a hollow case 21, a fan 22, a heat sink 23, two heat receiving members 24a and 24b, and a heat transfer member 25. As shown in FIG. 5, the cooling unit 15 is fixed to the wiring board 13 via a fixation member 20.

The cooling unit 15 is arranged in such a manner that the heat receiving members 24a and 24b make contact with the heat producing components 19, such as ICs and a CPU mounted on the wiring board. The fixation member 20 is formed of aluminum or copper excellent in thermal conductivity, and also has a role as a heat dissipating mechanism.

The case 21 is configured with a lower case 26 in a container shape and an upper case 27 overlapping with the lower case 26. The case 21 is formed in a thin, approximately perpendicular parallelepiped shape. In the case 21, the fan 22 is housed.

The lower case 26 has a placement surface 26a in a flat plate shape and a side wall 26b surrounding a partly eliminated periphery of the placement surface 26a. On the placement surface 26a, the fan 22 is mounted. The fan 22 is a sirocco fan that sucks the air axially and discharges the air tangentially. In the placement surface 26a, three lower air inlets 28 are formed so as to surround a place to mount the fan 22. From the lower air inlets 28, the air is sucked.

The side wall 26b is continually formed approximately vertically from the placement surface 26a. The side wall 26b is provided with a plurality of locking portions 29. The locking portions 29 are projections projecting upwardly vertically from the side wall 26b.

The upper case 27 is formed in an approximately flat plate shape and overlaps with the lower case 26 so as to face the placement surface 26a of the lower case 26. As shown in FIG. 5, the upper case 27 has a flat surface 27a and a side wall 27b. The side wall 27b is formed approximately vertically from a part of the circumference of the flat surface 27a.

In the flat surface 27a of the upper case 27, a circular upper air inlet 31 is formed. The upper air inlet 31 is located above the fan 22 mounted on the lower case 26 when the upper case 27 is overlaid on the lower case 26. On the circumference of the flat surface 27a, a plurality of lock receiving portions 32 are formed. The lock receiving portions 32 lock with the locking portions 29 of the lower case 26 when the upper case 27 is overlapped on the lower case 26. By overlapping the lower case 26 and the upper case 27, an air outlet 33 is formed to discharge the air.

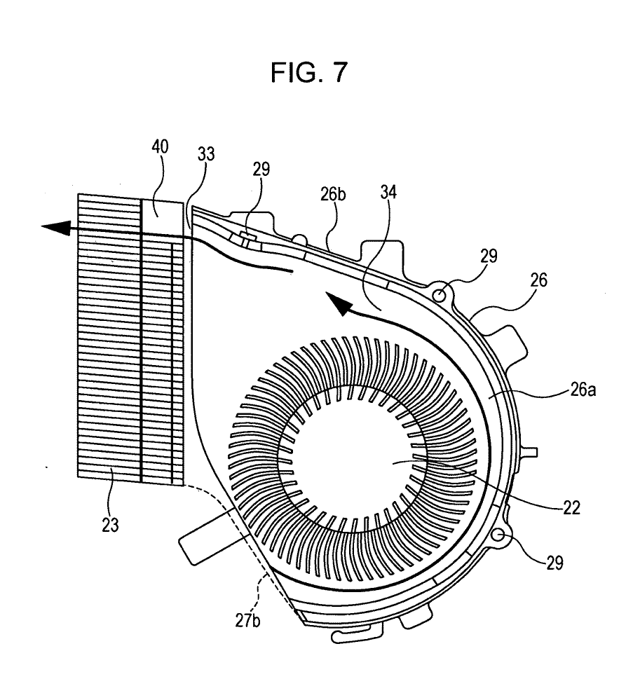

FIG. 7 is a front view illustrating the cooling unit of the embodiment in a condition of removing the upper case 27.

As shown in FIG. 7, a ventilation path 34 is formed by the side wall 26b of the lower case 26 and the side wall 27b of the upper case 27. The ventilation path 34 leads the air sucked by the lower air inlets 28 and the upper air inlet 31 to the air outlet 33. As shown in FIG. 3, the cooling unit 15 is arranged in such a manner that the air outlet 33 faces the position of the housing side air outlet 17 provided in the housing 8 of the laptop PC 1.

In the embodiment, the fan 22 rotates counterclockwise. Therefore, the air sucked by the lower air inlets 28 and the upper air inlet 31 is led counterclockwise along the side walls 26b and 27b similar to the direction of rotation of the fan 22. At this time, the side located on the left of the side walls 26b and 27b when viewing inside the case 21 from the air outlet 33 of the case 21 becomes a downstream side of the air flowing in the ventilation path 34.

In a case that the fan 22 rotates clockwise, the air flows clockwise along the side walls 26b and 27b. Therefore, the side located on the right of the side walls 26b and 27b when viewing inside the case 21 from the air outlet 33 of the case 21 becomes a downstream side of the flowing air.

The heat sink 23 is arranged so as to cover the air outlet 33 of the case 21. The heat sink 23 is configured with a plurality of heat dissipating fins 36. The heat sink 23 is mounted on the heat transfer member 25.

The heat transfer member 25 is a heat pipe having a liquid or a gas enclosed in a pipe. One end portion of the heat transfer member 25 is, as described above, connected to the heat sink 23, and the other end portion is connected to the first heat receiving member 24a. In the middle of the heat transfer member 25, the second heat receiving member 24b is mounted.

The heat transfer member 25 transfers the heat absorbed by the two heat receiving members 24a and 24b to the heat sink 23. As the type of material for the heat transfer member 25, materials excellent in thermal conductivity are preferred, and for example, copper, aluminum, or the like can be used.

Although an example of using two heat pipes as the heat transfer member 25 is described in the embodiment, embodiments of the present invention are not limited to it and the number of heat pipes configuring the heat transfer member is set appropriately in accordance with the expected cooling capacity.

The two heat receiving members 24a and 24b are formed of a type of material excellent in thermal conductivity, such as copper and aluminum. The first heat receiving member 24a is equipped with a fixation piece 30 to be connected to the fixation member 20 via a fixation screw.

As shown in FIG. 5, the first heat receiving member 24a is fixed to the fixation member 20 by a fixation method, such as a fixation screw, sandwiching the wiring board 13 in between. At this time, respective one side of the first heat receiving member 24a and the second heat receiving member 24b makes contact with the heat producing components, such as a CPU, that are not shown and mounted on a backside of the wiring board 13. Grease, a gel sheet or the like excellent in thermal conductivity may also be laid between the heat producing components and the first and second heat receiving members 24a and 24b.

### [Heat Sink]

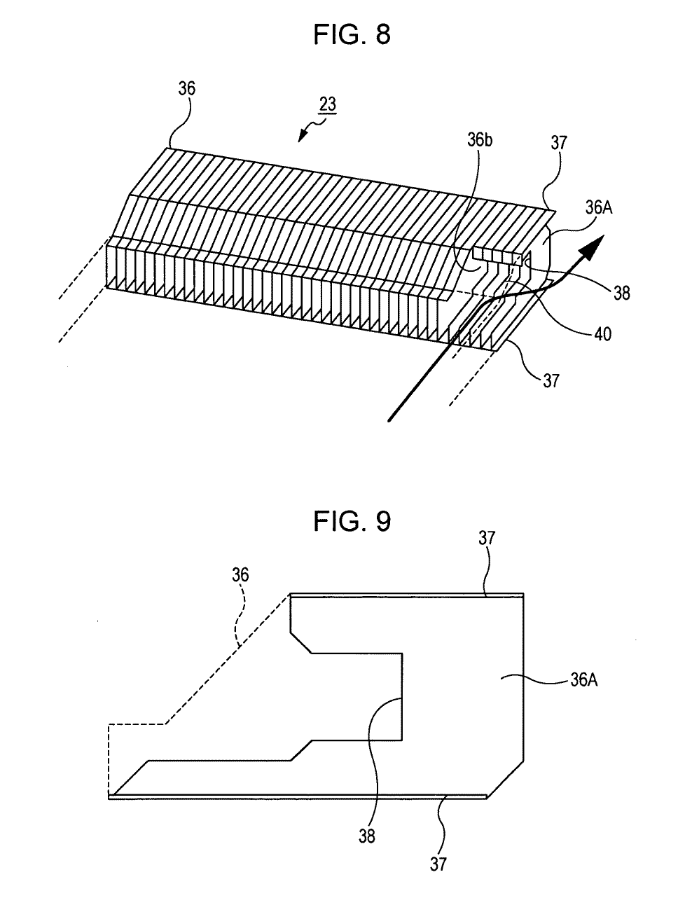

Next, a description is given to a detailed configuration of the heat sink 23 with reference to FIGS. 8 and 9.

FIG. 8 is a perspective view illustrating the heat sink 23, and FIG. 9 is a plan view illustrating the heat dissipating fins 36.

As shown in FIG. 8, the heat sink 23 is formed by stacking the plurality of heat dissipating fins 36 at predetermined intervals approximately in parallel and in an approximately perpendicular parallelepiped shape as a whole. The heat dissipating fins 36 are formed of thin plate materials. As shown in FIG. 9, the heat dissipating fins 36 are formed in an approximately trapezoidal shape and an upper side and a lower side in height are provided with folded portions 37. The folded portions 37 formed in the upper side and the lower side are folded approximately vertically in a same direction.

As the type of material for the heat dissipating fins 36, those excellent in thermal conductivity is preferred, and for example, copper, aluminum, or the like can be used.

As shown in FIG. 7, the heat sink 23 is arranged in such a manner that principal surfaces of the plurality of heat dissipating fins 36 are directed along the flow of the air discharged from the air outlet 33 of the case 21. This makes the air discharged from between the plurality of heat dissipating fins 36. By connecting the plurality of heat dissipating fins 36 with the folded portions 37, an upper surface and a lower face of the heat sink 23 become blocked surfaces (refer to FIG. 8).

The plurality of heat dissipating fins 36 arranged on one longitudinal side of the heat sink 23 have a role as dust and dirt discharging heat dissipating fins 36A to discharge dust and dirt. On a side to which the air sucked from the fan 22 in the dust and dirt discharging heat dissipating fins 36A is blown, a notch 38 is formed. This makes the dust and dirt discharging heat dissipating fins 36A configured in an approximately U shape. The size of the notch 38 is set appropriately depending on the cooling capacity expected to the heat sink 23 and the amount and the size of the dust and dirt to be discharged.

By the notch 38 formed in the dust and dirt discharging heat dissipating fins 36A, a dust and dirt discharging port 40 is formed. Since forming the notch 38 makes the dust and dirt easier to pass through than the other heat dissipating fins 36, the dust and dirt becomes less prone to pile up in the heat sink 23 as a whole. Accordingly, the dust and dirt discharging port 40 becomes a passage for the dust and dirt sucked together with the air by the fan 22. The dust and dirt discharging port 40 is equipped on the left when viewing inside the case 21 from the air outlet 33 of the case 21. Further, the size of the dust and dirt discharging port 40, that is, the size of the notch 38 formed in the dust and dirt discharging heat dissipating fins 36A and the number of heat dissipating fins 36 forming the notch 38 are set appropriately according to the cooling capacity expected to the heat sink 23.

In a case that the fan 22 rotates clockwise, the dust and dirt discharging port 40 is equipped on the right when viewing inside the case 21 from the air outlet 33 of the case 21. That is, the dust and dirt discharging port 40 is equipped at a position corresponding to the flow rate of the air flowing in the case 21. Specifically, the dust and dirt discharging port 40 is formed along the side walls 26b and 27b located on the downstream side of the air flowing along the ventilation path 34 in the side walls 26b and 27b of the case 21. Alternatively, it is formed by notching a predetermined number of the heat dissipating fins 36 adjacent to the heat dissipating fin 36 arranged in a place where the flow rate of the air passing between them is fastest among the plurality of heat dissipating fins 36.

The heat sink 23 having such a configuration is fixed to one end portion of the heat transfer member 25 by a fixation method, such as welding or adhesion. As shown in FIG. 4, when the cooling unit 15 is mounted on the housing 8 of the laptop PC 1, the heat sink 23 faces the housing side air outlet 17.

### 1-2. Behavior of Cooling Unit

Next, with reference to FIGS. 5 through 11, a description is given to a behavior of the cooling unit 15 having the configuration described above.

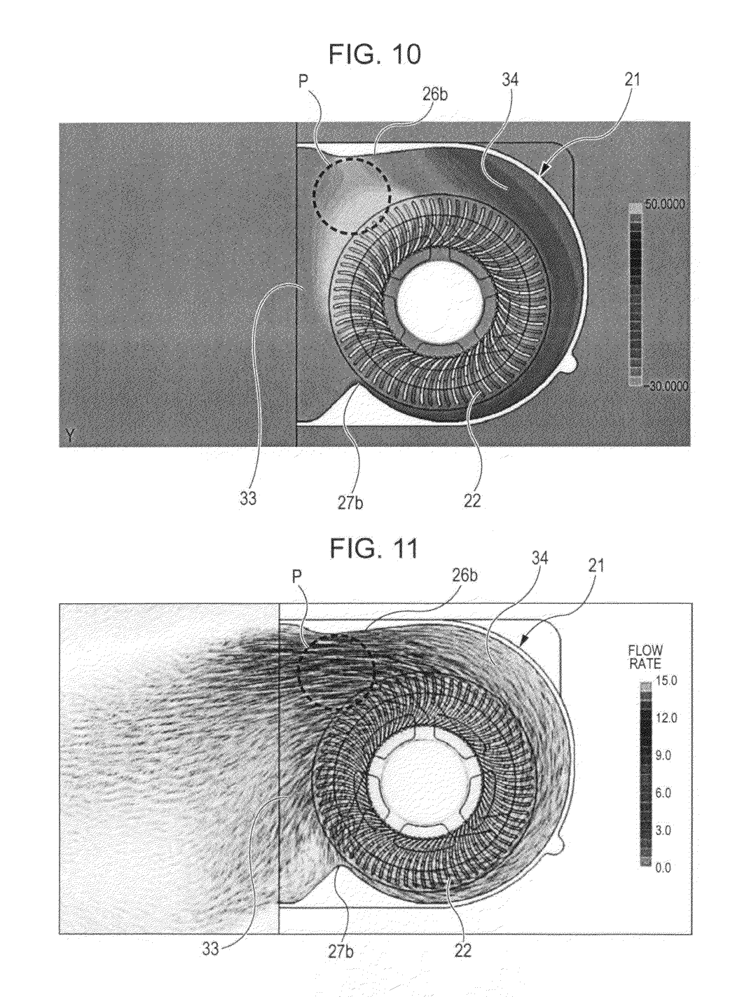

FIG. 10 is a pressure distribution chart illustrating the pressure inside the case 21 while the air flows, and FIG. 11 is a flow rate distribution chart illustrating the speed of the air flowing in the case 21. In FIG. 10, spots of dark colors represent high pressures and spots of light colors represent low pressures. In FIG. 11, spots of dark colors represent to be fast in flow rate and spots of light colors represent to be slow in flow rate.

In the cooling unit 15, the fan 22 rotates when the laptop PC 1, which is an electronic device, is driven. The rotation of the fan 22 is controlled by feeding back the temperature of the heat producing components 19. Regularly, when the temperature of the heat producing components 19 rises, the rotation number of the fan 22 increases, and when the temperature of the heat producing components 19 decreases, the rotation number of the fan 22 decreases.

Firstly, heat generated in the heat producing components 19 is transferred (absorbed) by the first heat receiving member 24a and the second heat receiving member 24b making contact with the heat producing components 19. The heat absorbed by the first heat receiving member 24a and the second heat receiving member 24b is transferred to the heat sink 23 via the heat transfer member 25.

When the fan 22 rotates, an air is sucked into the case 21 from the lower air inlets 28 and the upper air inlet of the case 21. As shown in FIG. 7, since the fan 22 rotates counterclockwise, the sucked air flows counterclockwise along the ventilation path 34 formed with the side walls 26b and 27b of the case 21. The air having flown in the ventilation path 34 is discharged from the air outlet 33 and is blown out to the heat sink 23.

The air blown to the heat sink 23 passes between the plurality of heat dissipating fins 36 and is discharged outside the cooling unit 15. Due to the air blown to the heat sink 23, the heat transferred to the heat sink 23 is dissipated and thus heat dissipation of the heat producing components 19 can be carried out. In order to effectively exhibit the cooling capacity of the heat sink 23, the interval between the heat dissipating fins 36 is preferably set as narrow as possible.

From the lower air inlets 28 and the upper air inlet 31, not only the air but also dust and dirt are sucked in the case 21. The dust and dirt sucked in the case 21 are swept radially outside the fan 22, that is, to the side walls 26b and 27b of the case 21 by a centrifugal force generated by the rotation of the fan 22. The dust and dirt pass through the ventilation path 34 together with the air along the side walls 26b and 27b of the case 21 and are discharged from the air outlet 33.

Here, a general manner of dust and dirt clogging is reviewed. Firstly, the dust and dirt discharged from the air outlet 33 is blown to the plurality of heat dissipating fins forming the heat sink 23. Once the dust and dirt are clogged in any one place in the plurality of heat dissipating fins 36, dust and dirt start to be clogged taking the place as a base point. Finally, dust and dirt turn out to cover the entire surface of the plurality of heat dissipating fins 36 configuring the heat sink 23 and the cooling capacity of the heat sink 23 seriously drops down.

By looking at the pressure distribution inside the case 21 shown in FIG. 10, it is found that a region P on the right when viewing inside the case 21 from the air outlet 33 of the case 21, that is, on a side of the side walls 26b and 27b located on a downstream side of the air in the side walls 26b and 27b is lowest in pressure. It is then found that a change in pressure in the region P is larger than that of other places. Therefore, as shown in FIG. 11, since the air is strongly blown in the low pressure region P, the flow rate of the air flowing in the region P becomes faster than that of other places.

Accordingly, the dust and dirt sucked in the case 21 and having flown in the ventilation path 34 together with the air along the side walls 26b and 27b can be assumed to be discharged intensely from the region P. It can also be assumed that the heat dissipating fins 36 of the heat sink 23 arranged in the vicinity of the region P becomes a base point of dust clogging. Here, the notch 38 is formed in the dust and dirt discharging heat dissipating fins 36A arranged in a place corresponding to the region P, which is on the right when viewing inside the case 21 from the air outlet 33 in the heat sink 23 to provide the dust and dirt discharging port 40. By providing the notch 38, dust and dirt are discharged easier and are less prone to be piled up than from other heat dissipating fins.

That is, the heat sink 23 is provided with the dust and dirt discharging port 40 corresponding to the place where the flow rate of the air discharged from the air outlet 33 becomes fastest. In this way, by providing the dust and dirt discharging port 40 in a place where the most dust and dirt are discharged and most likely to become a base point of dust clogging, a base point of generating dust and dirt clogging can be eradicated and also dust and dirt can be discharged effectively. As a result, dust clogging can be prevented efficiently. By partly notching the heat dissipating fins 36, the cooling capacity as the heat sink 23 can also be maintained.

Even when the dust and dirt are caught in the notch 38 of the dust and dirt discharging heat dissipating fins 36A configuring the dust and dirt discharging port 40, a flat surface of heat dissipating fins 36b arranged next to the dust and dirt discharging heat dissipating fins 36A shown in FIG. 8 becomes a protective barrier. That is, by making the flat surface of the heat dissipating fins 36b to be a protective barrier, the dust and dirt caught in the dust and dirt discharging heat dissipating fins 36A can be prevented from entering on the side of the other heat dissipating fins 36 and expansion of dust clogging can be prevented.

### 2. Another Embodiment

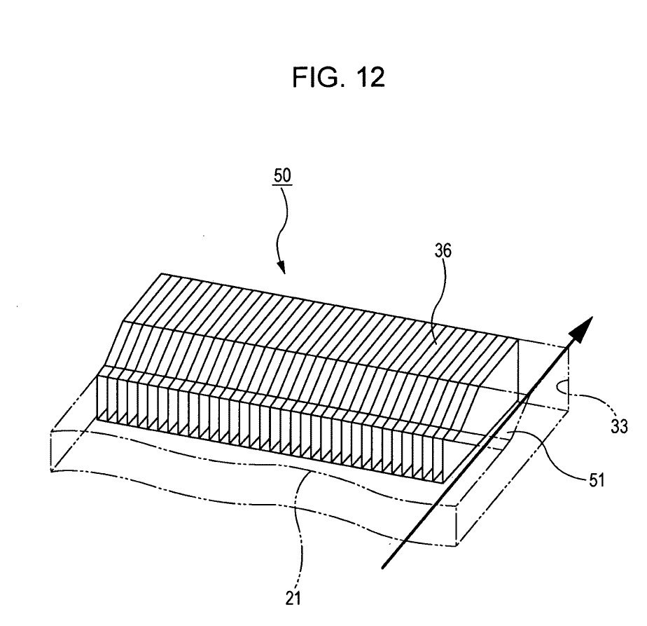

Next, with reference to FIG. 12, a description is given to a heat sink according to another embodiment of the present invention.

FIG. 12 is a perspective view illustrating a heat sink related to the other embodiment.

The point of a heat sink 50 related to this embodiment different from the heat sink 23 related to the former embodiment is a configuration of a dust and dirt discharging port. Therefore, in this section, a description is given to the dust and dirt discharging port and redundant descriptions for the parts in common with the heat sink 23 related to the former embodiment are omitted by assigning identical reference characters.

As shown in FIG. 12, on one longitudinal side of the heat sink 50, a dust and dirt discharging port 51 is provided. The dust and dirt discharging port 51 is configured from the dust and dirt discharging port 40 without the heat dissipating fins 36 arranged on the right when viewing inside the case 21 from the air outlet 33 of the case 21.

Since the other configurations are similar to the heat sink 23 related to the former embodiment described above, descriptions for them are omitted. It is also possible to obtain actions and effects similar to the heat sink 23 related to the former embodiment described above by the heat sink 50 having such a configuration.

According to the heat sink 50 related to this embodiment, the heat dissipating fins 36 are eliminated from the dust and dirt discharging port 51, so that dust clogging can be reduced even more than the heat sink 23 related to the former embodiment.

Embodiments of the present invention are not limited to the embodiments described above and illustrated in the drawings, and various modifications are available without departing from the scope described in the embodiments of the present invention. For example, although a description is given to examples of application to a laptop PC as the electronic device in the embodiments described above, the embodiments are not limited to them. The electronic device can be applied to, for example, desktop personal computers, electronic dictionaries, DVD players, car navigation systems, and other various types of electronic devices.

In addition, a dust and dirt discharging port may also be formed by making the interval between the heat dissipating fins arranged in a place where the flow rate of the air discharged from the air outlet becomes fastest wider than the interval between the heat dissipating fins arranged in the other places. The interval between the heat dissipating fins configuring the dust and dirt discharging port is set larger than the size of dust and dirt.

Further, although a description is given to examples of providing a dust and dirt discharging port only in one place in a heat sink in the embodiments described above, the embodiments are not limited to them. Dust and dirt discharging ports may also be provided in two or more places in a heat sink according to the flow rate of the air flowing in the case. The places to provide the dust and dirt discharging ports may be, for example, a place where the flow rate of the air discharged from the air outlet becomes fastest and a second fastest place, or may also be formed along the left and right side walls of the case.

It should be understood by those skilled in the art that various modifications, combinations, sub-combinations and alterations may occur depending on design requirements and other factors insofar as they are within the scope of the appended claims or the equivalents thereof.

What is claimed is:

1. A cooling unit comprising:
a case having an air inlet that sucks an air, an air outlet that discharges the sucked air, and a side wall that forms a ventilation path leading the air from the air inlet to the air outlet;
a fan housed in the case; and
a heat sink arranged in the air outlet of the case, having a plurality of heat dissipating fins, and having a dust and dirt discharging port formed at a position corresponding to a flow rate of the air flowing in the case.

2. The cooling unit according to claim 1, wherein the position to provide the dust and dirt discharging port is set by a direction of rotation of the fan.

3. The cooling unit according to claim 1 or 2, wherein the dust and dirt discharging port is formed along the side wall located on a downstream side when leading the air in the side wall.

4. The cooling unit according to any one of claims 1 through 3, wherein the dust and dirt discharging port is formed in a predetermined size from a heat dissipating fin arranged in a place where a flow rate of the air passing between them is fastest through an adjacent heat dissipating fin among the plurality of heat dissipating fins.

5. The cooling unit according to any one of claims 1 through 4, wherein the dust and dirt discharging port is formed by notching a heat dissipating fin arranged at a corresponding position among the plurality of heat dissipating fins.

6. The cooling unit according to any one of claims 1 through 4, wherein the dust and dirt discharging port is formed by eliminating a heat dissipating fin arranged at a corresponding position among the plurality of heat dissipating fins.

7. The cooling unit according to any one of claims 1 through 4, wherein
the plurality of heat dissipating fins are arranged at a predetermined interval, and
the dust and dirt discharging port is formed by making an interval between heat dissipating fins arranged at a corresponding position wider than an interval between other heat dissipating fins among the plurality of heat dissipating fins.

8. An electronic device, comprising:
a heat producing unit mounted on a substrate; and
a cooling unit cooling the heat producing unit; wherein
the cooling unit has
a case having an air inlet that sucks an air, an air outlet that discharges the sucked air, and a side wall that forms a ventilation path leading the air from the air inlet to the air outlet,
a fan housed in the case,
a heat sink arranged in the air outlet of the case, having a plurality of heat dissipating fins, and having a dust and dirt discharging port formed at a position corresponding to a flow rate of the air flowing in the case,
a heat receiving unit absorbing heat from the heat producing unit, and
a heat transfer unit transferring the heat absorbed by the heat receiving unit to the heat sink.

9. A heat sink, arranged in an air outlet of a cooling unit having an air inlet that has a fan built therein and sucks an air, the air outlet that discharges the sucked air, and a side wall that forms a ventilation path leading the air from the air inlet to the air outlet, the heat sink comprising:
a plurality of heat dissipating fins; and
a dust and dirt discharging port formed at a position corresponding to a flow rate of the air flowing in the case of the cooling unit.
